(19) United States
(12) Patent Application Publication
(10) Pub. No.: US 2016/0313414 A1
(43) Pub. Date: Oct. 27, 2016

(54) INFORMATION PROCESSOR, STORAGE MEDIUM, AND INFORMATION PROCESSING METHOD FOR MAGNETIC PROPERTY ANALYSIS

(71) Applicant: FUJITSU LIMITED, Kawasaki-shi (JP)

(72) Inventor: Koichi SHIMIZU, Inagi (JP)

(73) Assignee: FUJITSU LIMITED, Kawasaki-shi (JP)

(21) Appl. No.: 15/074,261

(22) Filed: Mar. 18, 2016

(30) Foreign Application Priority Data
Apr. 24, 2015 (JP) 2015-089621

(51) Int. Cl. G01R 33/12

(52) U.S. Cl. CPC G01R 33/12

(57) ABSTRACT

An information processor for magnetic property analysis, the information processor includes: an acquisition part to acquire a first magnetization vector and a second magnetization vector; and a generation part to generate an interpolation magnetization vector that has an initial point on a straight line connecting initial points of the acquired first magnetization vector and the acquired second magnetization vector and is directed in a plane identical to a plane in which the first magnetization vector and the second magnetization vector are directed.

### CROSS-REFERENCE TO RELATED APPLICATION

This application is based upon and claims the benefit of priority of the prior Japanese Patent Application No. 2015-089621, filed on Apr. 24, 2015, the entire contents of which are incorporated herein by reference.

### FIELD

The embodiments discussed herein are related to an information processor, a storage medium, and an information processing method for magnetic property analysis.

### BACKGROUND

Various magnetic property analysis methods have been proposed (see, for example, Japanese Laid-open Patent Publication No. 2004-184234, Japanese Laid-open Patent Publication No. 2003-98241, and Japanese Laid-open Patent Publication No. 2012-33116).

Such conventional methods are, however, problematic in that calculation errors are large. It is thus desired to provide an information processor and the like, which may increase the calculation accuracy.

### SUMMARY

According to an aspect of the invention, an information processor for magnetic property analysis includes: an acquisition part to acquire a first magnetization vector and a second magnetization vector; and a generation part to generate an interpolation magnetization vector that has an initial point on a straight line connecting initial points of the acquired first magnetization vector and the acquired second magnetization vector and is directed in a plane identical to a plane in which the first magnetization vector and the second magnetization vector are directed

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram that illustrates a hardware group of an information processor;

FIG. 2 is an explanatory diagram that illustrates a state where a magnetic substance is modeled through micromagnetization;

FIG. 3 is an explanatory diagram that illustrates magnetization vectors;

FIG. 4 is an explanatory diagram that illustrates magnetization vectors;

FIG. 5 is a graph that illustrates variations in gradient of a magnetization vector;

FIG. 6 is an explanatory diagram that illustrates an intermediate magnetization vector;

FIG. 7 is a graph that illustrates contrast to intermediate magnetization;

FIG. 8 is an explanatory diagram that illustrates magnetization vectors;

FIG. 9 is an explanatory diagram that illustrates interpolation magnetization vectors;

FIG. 10 is a graph that illustrates contrast to an interpolation magnetization vector;

FIG. 11 is a flow chart that illustrates a procedure of a generation process of an interpolation magnetization vector;

FIG. 12 is an explanatory diagram that illustrates magnetization vectors;

FIG. 13 is a graph that illustrates magnetization vectors;

FIG. 14 is an explanatory diagram that illustrates magnetization vectors;

FIGS. 15 and 16 are flow charts that illustrate a calculation procedure of an exchange coupling magnetic field;

FIG. 17 is an explanatory chart that illustrates meshes used in experiments;

FIG. 18 is a graph that illustrates changes in coercivity of hexahedrons;

FIG. 19 is a graph that illustrates changes in coercivity of tetrahedrons;

FIG. 20 is a functional block diagram that illustrates operation of a computer according to an embodiment; and

FIG. 21 is a block diagram that illustrates a hardware group of a computer according to an embodiment.

### DESCRIPTION OF EMBODIMENTS

### Embodiment 1

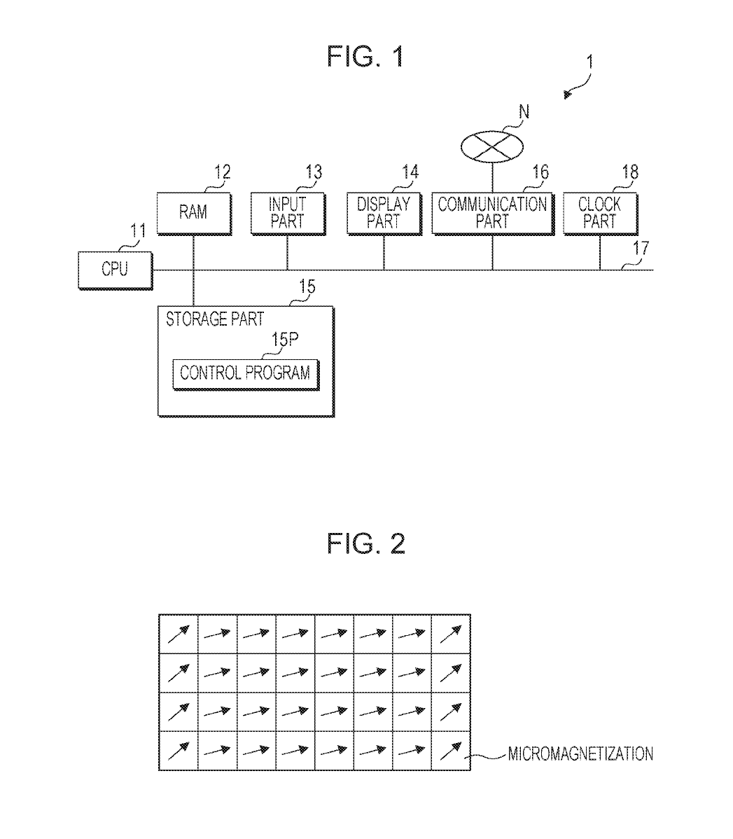

Embodiments are described below with reference to the drawings. FIG. 1 is a block diagram that illustrates a hardware group of an information processor 1. An information processor 1 is, for example, a server computer, a personal computer, a personal digital assistant (PDA), or a smartphone. The information processor 1 is hereinafter referred to as the computer 1. The computer 1 includes a central processing unit (CPU) 11 as a control part, random access memory (RAM) 12, an input part 13, a display part 14, a storage part 15, a communication part 16, and a clock part 18.

The CPU 11 is coupled to each hardware constituent via a bus 17. The CPU 11 controls each hardware constituent in accordance with a control program 15P stored in the storage part 15. The RAM 12 is, for example, static RAM (SRAM), dynamic RAM (DRAM), or flash memory. The RAM 12 functions as a storage part and temporarily stores various data caused when the CPU 11 executes various programs.

The input part 13 is an input device, such as a keyboard, a mouse, or a touch panel, and outputs accepted operation information to the CPU 11. The display part 14 is a liquid crystal display, an organic electroluminescence (EL) display, or the like and displays various kinds of information in accordance with instructions from the CPU 11. The clock part 18 outputs information on a date and time to the CPU 11. The communication part 16 is a communication module, and performs transmission and reception of information with another computer, which is not illustrated, through a communication network N, such as the Internet. The storage part 15 is a hard disk or bulk memory and stores the control program 15P for example.

FIG. 2 is an explanatory diagram that illustrates a state where a magnetic substance is modeled through micromagnetization. The micromagnetics simulation is a technique of performing a numerical simulation on a magnetic domain state by modeling a magnetic substance as an aggregate of small magnets as illustrated in FIG. 2. Based on the micromagnetics, each individual small magnet may be herein referred to as a micromagnetization. In view of calculation costs, the micromagnetics simulation uses a mesh of several nm instead of using a mesh of actual atom size order. A mesh size generally used is adjusted so that an angle formed by magnetization vectors of adjacent meshes is small and calculated so that the magnetization directions are almost continuous.

An equation that governs movement of the micromagnetization, that is, a governing equation referred to as the Landau-Lifshitz-Gilbert (LLG) equation hereinafter is indicated in Mathematical Expression (1).

$$\frac{\partial \vec{m}}{\partial t} = - \frac{γ}{1 + {α}^{2}} \vec{m} \times {\vec{H}}_{eff} - \frac{1}{1 + {α}^{2}} \frac{α γ}{{M}_{s}} \vec{m} \times ( \vec{m} \times {\vec{H}}_{eff} ) \vert \vec{m} \vert = 1 \qquad ( 1 )$$

\vec{m}: Magnetization vector

γ: Gyromagnetic ratio

α: Friction coefficient

H_{eff}: Effective magnetic field

Mₛ: Saturation magnetization

t: Time

As indicated in Mathematical Expression (2), an effective magnetic field H_{eff} is synthesized from a plurality of magnetic field vectors, which include an external magnetic field Hₒᵤₜ, a demagnetic field H_{demag}, an anisotropic magnetic field Hₐₙ, and a magnetic exchange coupling magnetic field Hₑₓ.

\vec{H}_{eff}=\vec{H}ₒᵤₜ+\vec{H}_{demag}+\vec{H}ₐₙ+\vec{H}ₑₓ 92)

The magnetic fields that the micromagnetization receives are the external magnetic field Hₒᵤₜ, the demagnetic field H_{demag} indicated in Mathematical Expression (3), the anisotropic magnetic field Hₐₙ indicated in Mathematical Expression (4), and the magnetic exchange coupling magnetic field Hₑₓ indicated in Mathematical Expression (5). Herein, φ represents a magnetostatic potential, Mₛ represents a saturation magnetization, Kᵤ represents a magnetic anisotropic constant, and u represents a magnetic anisotropic vector, and as to the vectors, superscript arrows are omitted when desirable. Further, A represents an exchange coupling constant. The magnetic exchange coupling magnetic field Hₑₓ is force that acts between adjacent atoms, originally. To perform analysis that maintains the calculation accuracy while using an analysis model that has undergone mesh splitting so as to have a size larger than an inter-atom distance, the mesh splitting is performed so that an angle change of an adjacent magnetization vector is small to a certain extent.

$$\begin{matrix}{\vec{H}}_{demag} = - ∇ φ & ( 3 ) \\ {\vec{H}}_{an} = \frac{2 {K}_{u}}{{M}_{s}} ( \vec{m} \cdot \vec{u} ) \vec{u} & ( 4 ) \\ {\vec{H}}_{ex} = \frac{2 A}{{M}_{S}} {∇}^{2} \vec{m} & ( 5 )\end{matrix}$$

Subsequently, a linear implicit method is described. The linear implicit method is a technique by which each time increment is increased by applying the implicit method to the LLG equation, which is an ordinary differential equation of a magnetization vector and speedup in calculation is enabled. The LLG equation is nonlinear with respect to a magnetization vector and therefore, expression by a linear equation with respect to the magnetization vector is impossible without adding any change. The linearization is performed by using the magnetization vector mⁿ⁺¹ at the subsequent time step for the magnetization vectors included in the anisotropic magnetic field and the exchange coupling magnetic field. The right-hand side of the LLG equation indicated in Mathematical Expression (1) includes a term of the first power of a magnetization vector m and a term of the square of m, which is an unknown quantity.

Since the anisotropic magnetic field Hₐₙ and the exchange coupling magnetic field Hₑₓ may also be expressed with the first power of m, the right-hand side of the LLG equation includes terms of the square and the cube of m. Although being nonlinear regarding m, the LLG equation may be linearized regarding mⁿ⁺¹ by treating m appearing in the anisotropic magnetic field and the exchange coupling magnetic field implicitly (m^{n30 1}) and treating the other m explicitly (mⁿ). Described below is derivation of expressions regarding the linear implicit method. Mathematical Expression (7) may be obtained by applying a formula of the vector analysis indicated in Mathematical Expression (6) to the second term on the right-hand side of the LLG equation.

\vec{A}×(\vec{B}×\vec{C})=(\vec{A}·\vec{C})\vec{B}−(\vec{A}·\vec{B})\vec{C} (6)

\vec{m}×(\vec{m}×\vec{H}_{eff})=(\vec{m}·\vec{H}_{eff})\vec{m}−(\vec{m}·\vec{m})\vec{H}_{eff}=9\vec{m}·\vec{H}_{eff})\vec{m}−\vec{H}_{eff} (7)

Mathematical Expression (8) may be obtained by ignoring (=0) the first term (precession) on the right-hand side of the LLG equation, substituting Mathematical Expression (7) for the second term (friction term) on the right-hand side, and performing rewriting as a damping constant (or friction coefficient) α=1.

$$\frac{\partial \vec{m}}{\partial t} = \frac{γ}{2 {M}_{s}} [ {H}_{eff} - ( \vec{m} \cdot {\vec{H}}_{eff} ) \vec{m} ] \qquad ( 8 )$$

When the linear implicit method is applied to Mathematical Expression (8) with regard to the magnetizations mᵢ of a plurality of meshes (i=0 to N), Mathematical Expression (9) is obtained.

$$\frac{{\vec{m}}_{i}^{n + 1} - {\vec{m}}_{i}^{n}}{\partial t} = \frac{γ}{2 {M}_{s}} [ {H}_{eff}^{n + 1} - ( {\vec{m}}_{i}^{n} \cdot {H}_{eff}^{n + 1} ) {\vec{m}}_{i}^{n} ] \qquad ( 9 )$$

Subsequently, the term regarding mⁿ⁺¹ is transposed to the left-hand side and the term regarding mⁿ is transposed to the right-hand side. In the effective magnetic field N_{eff}, the anisotropic magnetic field Hₐₙ and the magnetic exchange coupling magnetic field Hₑₓ may be expressed by linear combination of mⁿ⁺¹ and are thus transposed to the left-hand side, and the others, which are the external magnetic field Hₒᵤₜ and the demagnetic field H_{demag} are transposed to the right-hand side. The left-hand side and the right-hand side of Mathematical Expression (9) after the transposition may be expressed by Mathematical Expressions (10) and (11), respectively. The expression in [ ] on the front side of { } in Mathematical Expression (10) contributes to the anisotropic magnetic field and the expression in [ ] on the rear side of { } in Mathematical Expression (10) contributes to the exchange coupling magnetic field. Hereinafter, the coefficient matrix in [ ] on the front side is denoted as Gₐₙ and the coefficient matrix in [ ] on the rear side is denoted as Gₑₓ.

$$\begin{matrix}\frac{{\vec{m}}_{i}^{n + 1}}{Δ t} - \frac{γ}{2 {M}_{s}} \{ [ {H}_{an}^{n + 1} - ( {\vec{m}}_{i}^{n} \cdot {H}_{an}^{n + 1} ) {\vec{m}}_{i}^{n} ] + [ {H}_{ex}^{n + 1} - ( {\vec{m}}_{i}^{n} \cdot {H}_{ex}^{n + 1} ) {\vec{m}}_{i}^{n} ] \} & ( 10 ) \\ \frac{{\vec{m}}_{i}^{n}}{Δ t} + \frac{γ}{2 {M}_{s}} \{ [ {H}_{out}^{n + 1} - ( {\vec{m}}_{i}^{n} \cdot {H}_{out}^{n + 1} ) {\vec{m}}_{i}^{n} ] + [ {H}_{demag}^{n + 1} - ( {\vec{m}}_{i}^{n} \cdot {H}_{demag}^{n + 1} ) {\vec{m}}_{i}^{n} ] \} & ( 11 )\end{matrix}$$

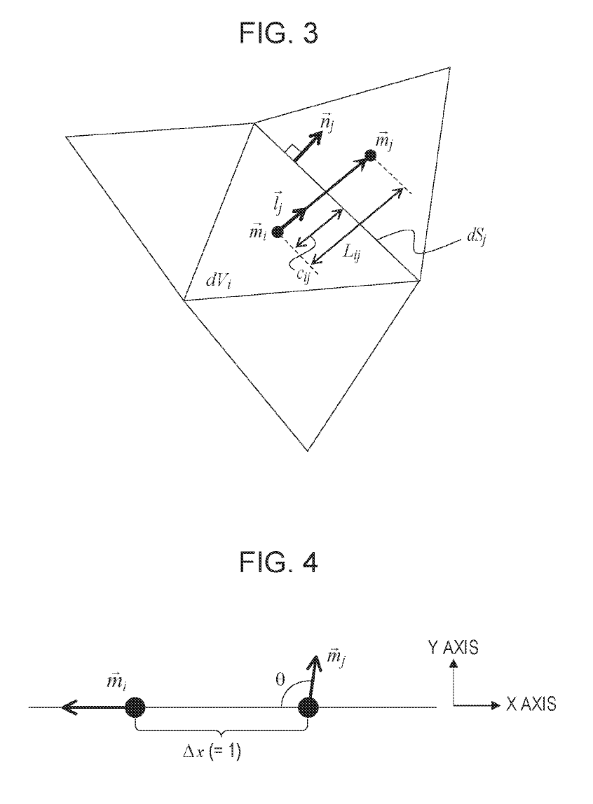

FIG. 3 is an explanatory diagram that illustrates magnetization vectors. In the linear implicit method, simultaneous equations regarding the magnetization vector mₙ₊₁ are expressed in the form of coefficient matrices and a solution mᵢⁿ⁺¹ is determined by solving the large-scale simultaneous equations. The X-axis direction component of the magnetic field caused through the exchange coupling with respect to the magnetization vector mᵢ of interest depends on a distance Lᵢⱼ between the barycenters of the magnetization vector mᵢ and the adjacent magnetization vector an area dSⱼ, a unit direction vector a normal vector nⱼ of the plane, a volume dVᵢ of the element of its own and is expressed by Mathematical Expression (12).

$${H}_{ex , x} = \frac{1}{d {V}_{i}} \frac{2 A}{{M}_{S}} {{\sum }^{Nf}}_{j = 1} \vec{∇} {m}_{x} d {\vec{S}}_{j} = \frac{1}{d {V}_{i}} \frac{2 A}{{M}_{S}} {{\sum }^{Nf}}_{j = 1} \frac{{m}_{x , j} - {m}_{x , i}}{{L}_{ij}} {\vec{n}}_{j} \cdot {\vec{l}}_{j} d {S}_{j} \qquad ( 12 )$$

When the directions are generalized, the magnetic field caused through the exchange coupling may be expressed by Mathematical Expression (13).

$${\vec{H}}_{ex} \frac{1}{d {V}_{i}} \frac{2 A}{{M}_{S}} {{\sum }_{j = 1}}^{Nf} \vec{∇} \vec{m} d {\vec{S}}_{j} = \frac{1}{d {V}_{i}} \frac{2 A}{{M}_{S}} {{\sum }_{j = 1}}^{Nf} \frac{{\vec{m}}_{j} - {\vec{m}}_{i}}{{L}_{ij}} {\vec{n}}_{j} \cdot {\vec{l}}_{j} d {S}_{j} \qquad ( 13 )$$

The magnetic field Hₑₓ caused through the exchange coupling depends on the direction of the adjacent magnetization vector mⱼ. When the equation of the linear implicit method is expressed using matrices, Mathematical Expression (14) is obtained.

$$( \begin{matrix}{\overleftrightarrow{G}}_{11} & {\overleftrightarrow{G}}_{12} & … & {\overleftrightarrow{G}}_{1 m} \\ {\overleftrightarrow{G}}_{21} & {\overleftrightarrow{G}}_{22} & & \\ ⋮ & & & ⋮ \\ {\overleftrightarrow{G}}_{m 1} & & … & {\overleftrightarrow{G}}_{mm}\end{matrix} ) ( \begin{matrix}{\vec{m}}_{1}^{n + 1} \\ {\vec{m}}_{2}^{n + 1} \\ ⋮ \\ {\vec{m}}_{m}^{n + 1}\end{matrix} ) = ( \begin{matrix}{\vec{F}}_{1} \\ {F}^{{\to }_{2}} \\ ⋮ \\ {\vec{F}}_{m}\end{matrix} ) \qquad ( 14 )$$

Here, the vector Gᵢⱼ is a 3×3 matrix dependent on the vector mᵢⁿ of the previous step and the vector Fᵢ is a 3×1 vector dependent on the vector mᵢⁿ of the previous step. Calculating Mathematical Expression (15) enables the magnetization vector mᵢⁿ⁺¹ of the subsequent step n+1 to be calculated.

\vec{m}ᵢⁿ⁺¹= [symbol] ᵢⱼ⁻¹\vec{F}ᵢ (15)

The vector Fᵢ may be determined by Mathematical Expression (16).

$${\vec{F}}_{i} = \frac{{\vec{m}}_{i}^{n}}{Δ t} + \frac{γ}{2 {M}_{s}} \{ [ {H}_{out}^{n + 1} - ( {\vec{m}}_{i}^{n} \cdot {H}_{out}^{n + 1} ) {\vec{m}}_{i}^{n} ] + [ {H}_{demag}^{n + 1} - ( {\vec{m}}_{i}^{n} \cdot {H}_{demag}^{n + 1} ) {\vec{m}}_{i}^{n} ] \} \qquad ( 16 )$$

Calculated below is the coefficient matrix dependent on an anisotropic magnetic field and the exchange coupling magnetic field. The coefficient matrix Gₐₙ in Mathematical Expression (10), which relates to the anisotropic magnetic field, may be expressed by Mathematical Expression (18) through Mathematical Expression (17) and may finally be expressed by Mathematical Expression (19).

$$\begin{matrix}\frac{{\vec{m}}_{i}^{n + 1}}{Δ t} - \frac{γ K}{{M}_{s}} [ ( {\vec{m}}_{i}^{n + 1} \cdot \vec{u} ) \vec{u} - {\vec{m}}_{i}^{n} \cdot [ ( {\vec{m}}_{i}^{n + 1} \cdot \vec{u} ) ] {\vec{m}}_{i}^{n} ] & ( 17 ) \\ {G}_{an} ( \begin{matrix}{m}_{i , x}^{n + 1} \\ {m}_{i , y}^{n + 1} \\ {m}_{i , z}^{n + 1}\end{matrix} ) = \frac{γ}{2} ( \begin{matrix}- {H}_{k} {u}_{i , x} \cdot {u}_{i , x} + & - {H}_{k} {u}_{i , y} \cdot {u}_{i , x} + & - {H}_{k} {u}_{i , z} \cdot {u}_{i , x} + \\ {λ}_{i} {u}_{i , x} \cdot {m}_{i , x}^{n} & {λ}_{i} {u}_{i , y} \cdot {m}_{i , x}^{n} & {λ}_{i} {u}_{i , z} \cdot {m}_{i , x}^{n} \\ - {H}_{k} {u}_{i , x} \cdot {u}_{i , y} & - {H}_{k} {u}_{i , y} \cdot {u}_{i , y} & - {H}_{k} {u}_{i , z} \cdot {u}_{i , y} \\ {λ}_{i} {u}_{i , x} \cdot {m}_{i , y}^{n} & {λ}_{i} {u}_{i , y} \cdot {m}_{i , y}^{n} & {λ}_{i} {u}_{i , z} \cdot {m}_{i , y}^{n} \\ - {H}_{k} {u}_{i , x} \cdot {u}_{i , z} & - {H}_{k} {u}_{i , y} \cdot {u}_{i , z} & - {H}_{k} {u}_{i , z} \cdot {u}_{i , z} \\ {λ}_{i} {u}_{i , x} \cdot {m}_{i , z}^{n} & {λ}_{i} {u}_{i , y} \cdot {m}_{i , z}^{n} & {λ}_{i} {u}_{i , z} \cdot {m}_{i , z}^{n}\end{matrix} ) ( \begin{matrix}\begin{matrix}{m}_{i , x}^{n + 1} \\ {m}_{i , y}^{n + 1}\end{matrix} \\ {m}_{i , z}^{n + 1}\end{matrix} ) where , {H}_{k} = \frac{2 K}{{M}_{s}} {λ}_{i} = {H}_{k} {\vec{m}}_{i}^{n} \cdot {\vec{u}}_{i} & ( 18 ) \\ {G}_{i , an} = \frac{γ}{2} ( \begin{matrix}- {H}_{k} {u}_{i , x} \cdot {u}_{i , x} & - {H}_{k} {u}_{i , y} \cdot {u}_{i , x} & - {H}_{k} {u}_{i , z} \cdot {u}_{i , x} \\ {λ}_{i} {u}_{i , x} \cdot {m}_{i , x}^{n} & {λ}_{i} {u}_{i , y} \cdot {m}_{i , x}^{n} & {λ}_{i} {u}_{i , z} \cdot {m}_{i , x}^{n} \\ - {H}_{k} {u}_{i , x} \cdot {u}_{i , y} & - {H}_{k} {u}_{i , y} \cdot {u}_{i , y} & - {H}_{k} {u}_{i , z} \cdot {u}_{i , y} \\ {λ}_{i} {u}_{i , x} \cdot {m}_{i , y}^{n} & {λ}_{i} {u}_{i , y} \cdot {m}_{i , y}^{n} & {λ}_{i} {u}_{i , z} \cdot {m}_{i , y}^{n} \\ - {H}_{k} {u}_{i , x} \cdot {u}_{i , z} & - {H}_{k} {u}_{i , y} \cdot {u}_{i , z} & - {H}_{k} {u}_{i , z} \cdot {u}_{i , z} \\ {λ}_{i} {u}_{i , x} \cdot {m}_{i , z}^{n} & {λ}_{i} {u}_{i , y} \cdot {m}_{i , z}^{n} & {λ}_{i} {u}_{i , z} \cdot {m}_{i , z}^{n}\end{matrix} ) & ( 19 )\end{matrix}$$

The coefficient matrix Gₑₓ in Mathematical Expression (10), which relates to the exchange coupling magnetic field, may be expressed by Mathematical Expressions (21) and (22) through Mathematical Expression (20). Here, i represents its own element and j represents contribution from the adjacent element.

$$\begin{matrix} - \frac{γ A}{{M}_{s}} [ {∇}^{2} {\vec{m}}_{i}^{n + 1} - {\vec{m}}_{i}^{n} \cdot ( {∇}^{2} {\vec{m}}_{i}^{n + 1} ) {\vec{m}}_{i}^{n} ] & ( 20 ) \\ {G}_{ex} ( \begin{matrix}{m}_{i , x}^{n + 1} - {m}_{j , x}^{n + 1} \\ {m}_{i , y}^{n + 1} - {m}_{j , y}^{n + 1} \\ {m}_{i , z}^{n + 1} - {m}_{j , z}^{n + 1}\end{matrix} ) = - {c}_{i , j} ( \begin{matrix}1 - {m}_{i , x}^{n} {m}_{i , x}^{n} & - {m}_{i , y}^{n} {m}_{i , x}^{n} & - {m}_{i , z}^{n} {m}_{i , x}^{n} \\ - {m}_{i , x}^{n} {m}_{i , y}^{n} & 1 - {m}_{i , y}^{n} {m}_{i , y}^{n} & - {m}_{i , z}^{n} {m}_{i , y}^{n} \\ - {m}_{i , x}^{n} {m}_{i , z}^{n} & - {m}_{i , y}^{n} {m}_{i , z}^{n} & 1 - {m}_{i , z}^{n} {m}_{i , z}^{n}\end{matrix} ) ( \begin{matrix}{m}_{i , x}^{n + 1} - {m}_{j , x}^{n + 1} \\ {m}_{i , y}^{n + 1} - {m}_{j , y}^{n + 1} \\ {m}_{i , z}^{n + 1} - {m}_{j , z}^{n + 1}\end{matrix} ) where , {c}_{i , j} = - \frac{γ A}{{M}_{s}} \frac{d {S}_{i} {\vec{l}}_{j} \cdot {\vec{n}}_{j}}{d {V}_{i} {L}_{ij}} & ( 21 ) \\ {G}_{ij , ex} = {c}_{i , j} ( \begin{matrix}1 - {m}_{i , x}^{n} {m}_{i , x}^{n} & - {m}_{i , y}^{n} {m}_{i , x}^{n} & - {m}_{i , z}^{n} {m}_{i , x}^{n} \\ - {m}_{i , x}^{n} {m}_{i , y}^{n} & 1 - {m}_{i , y}^{n} {m}_{i , y}^{n} & - {m}_{i , z}^{n} {m}_{i , y}^{n} \\ - {m}_{i , x}^{n} {m}_{i , z}^{n} & - {m}_{i , y}^{n} {m}_{i , z}^{n} & 1 - {m}_{i , z}^{n} {m}_{i , z}^{n}\end{matrix} ) & ( 22 )\end{matrix}$$

When the adjacent contribution is expressed using Mathematical Expressions (10), (11), and (21) in the form of matrices while being included explicitly, Mathematical Expression (23) is obtained. Stable calculation may be enabled by causing the adjacent magnetization vector mⱼⁿ⁺¹ to be included in the matrix on the left-hand side even when each time increment is increased.

$$( \frac{I}{Δ t} + {G}_{i , an} + {G}_{ij , ex} ) ( \begin{matrix}{m}_{i , x}^{n + 1} \\ {m}_{i , y}^{n + 1} \\ {m}_{i , z}^{n + 1}\end{matrix} ) - {G}_{ij , ex} ( \begin{matrix}\begin{matrix}{m}_{j , x}^{n + 1} \\ {m}_{j , y}^{n + 1}\end{matrix} \\ {m}_{j , z}^{n + 1}\end{matrix} ) = {\vec{F}}_{i}^{n} = ( \begin{matrix}{F}_{i , x}^{n} \\ {F}_{i , y}^{n} \\ {F}_{i , z}^{n}\end{matrix} ) \qquad ( 23 )$$

To express all the matrices for the element i as a whole while G represents the sum of the matrix of the exchange coupling where I/Δt, the anisotropy, and the adjacent contribution are taken into account, Mathematical Expression (24) may be obtained.

[G]{\vec{m}ⁿ⁺¹}={\vec{F}ⁿ} (24)

The magnetization vector at subsequent point of time may be determined as indicated in Mathematical Expression (25) by solving the whole simultaneous equations.

{\vec{m}ⁿ⁺¹}=[G]⁻¹{\vec{F}ⁿ} (25)

FIG. 4 is an explanatory diagram that illustrates magnetization vectors. The intermediate magnetization is now described. A magnetization vector M may be expressed by the product of the unit magnetization vector m and a saturation magnetization Mₛ, that is, so that M=Mₛm. Described below is the unit magnetization vector m. The magnetic field caused by the exchange coupling of the adjacent magnetization j with respect to the magnetization i is proportional to the gradient of the magnetization vector indicated in Mathematical Expression (26) (see Mathematical Expression (13)).

$$\frac{d \vec{m}}{d x} = \frac{{\vec{m}}_{j} - {\vec{m}}_{i}}{Δ x} \qquad ( 26 )$$

The Y-axis component of the gradient largely contributes to a torque that rotates the magnetization vector mᵢ. Thus, only the Y-axis direction component of the gradient is hereinafter taken into account through simplification into Δx=1. If the gradient is calculated based on the concept of conventional differentiation without adding any change, the Y component of the gradient is attenuated when the rotation angle θ exceeds 90 degrees.

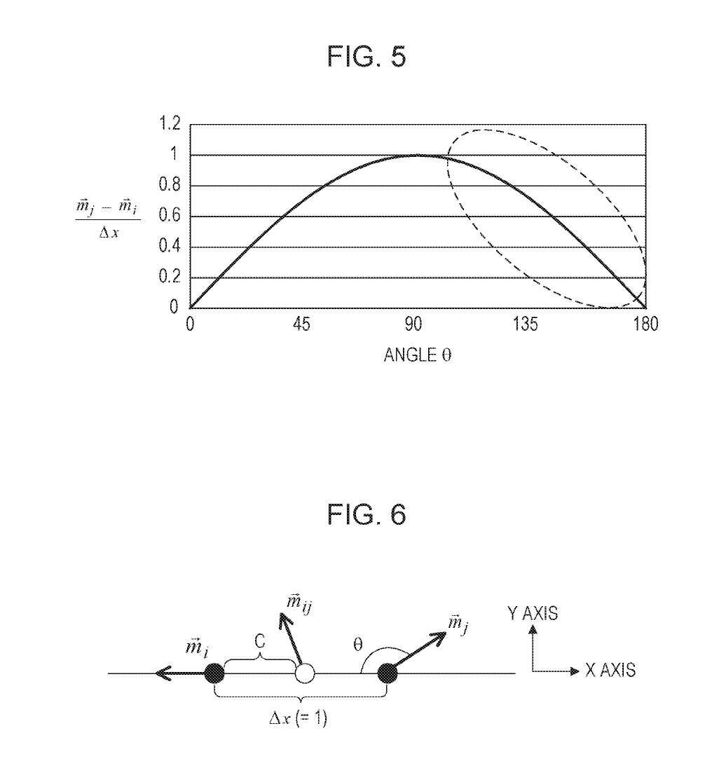

FIG. 5 is a graph that illustrates variations in the gradient of the magnetization vector. In the graph in FIG. 5, the Y-axis component of the gradient of the magnetization vector calculated by a conventional technique is plotted along the horizontal axis as the angle θ formed by two magnetization vectors. As indicated by the dashed line in FIG. 5, when the angle θ exceeds 90 degrees, attenuation occurs and a calculation error becomes large.

When the mesh width is decreased, the angle formed by the magnetization vectors adjacent to each other becomes small and thus, the magnetic field caused through the exchange coupling may be calculated with high accuracy. When the mesh width is decreased, however, the number of meshes as a whole becomes large and thus, the calculation time is increased. As a technique of calculating the magnetic field caused through the exchange coupling (the gradient of the magnetization vector) with high accuracy even while the mesh width is not necessarily small, an intermediate magnetization vector is used.

FIG. 6 is an explanatory diagram that illustrates an intermediate magnetization vector mᵢⱼ. The intermediate magnetization vector mᵢⱼ is a virtual magnetization vector positioned between two magnetization vectors. As indicated in Mathematical Expression (27), the intermediate magnetization vector interpolated between the two magnetization vectors is obtained by standardizing the virtual magnetization vector with the length thereof (the length=1). The attenuation of the gradient may be suppressed by calculating the gradient of the magnetic field using the intermediate magnetization vector.

$${\vec{m}}_{ij} = \frac{( 1 - c ) {\vec{m}}_{i} + c {\vec{m}}_{j}}{\vert ( 1 - c ) {\vec{m}}_{i} + c {\vec{m}}_{j} \vert} \qquad ( 27 )$$

As indicated in Mathematical Expression (28), c represents a value obtained by standardizing the position of the magnetization vector mᵢⱼ in FIG. 3 with the distance.

$$c = \frac{{c}_{ij}}{{L}_{ij}} \qquad ( 28 )$$

The magnetic field caused through the exchange coupling using the intermediate magnetization may be expressed by Mathematical Expression (29).

$${\vec{H}}_{ex}^{c} = \frac{1}{d {V}_{i}} \frac{2 A}{{M}_{S}} {\sum }_{j = 1}^{Nf} \frac{{\vec{m}}_{ij} - {\vec{m}}_{i}}{{cL}_{ij}} {\vec{n}}_{j} \cdot {\vec{l}}_{j} d {S}_{j} \qquad ( 29 )$$

When the gradient is calculated using the intermediate magnetization, the attenuation decreases even if the angle increases. That is, the use of the intermediate magnetization may enable the gradient to be calculated with high accuracy to a larger magnetization change of the angle, compared to the conventional technique, and thus, the calculation with the same accuracy may be performed with the larger mesh spacing.

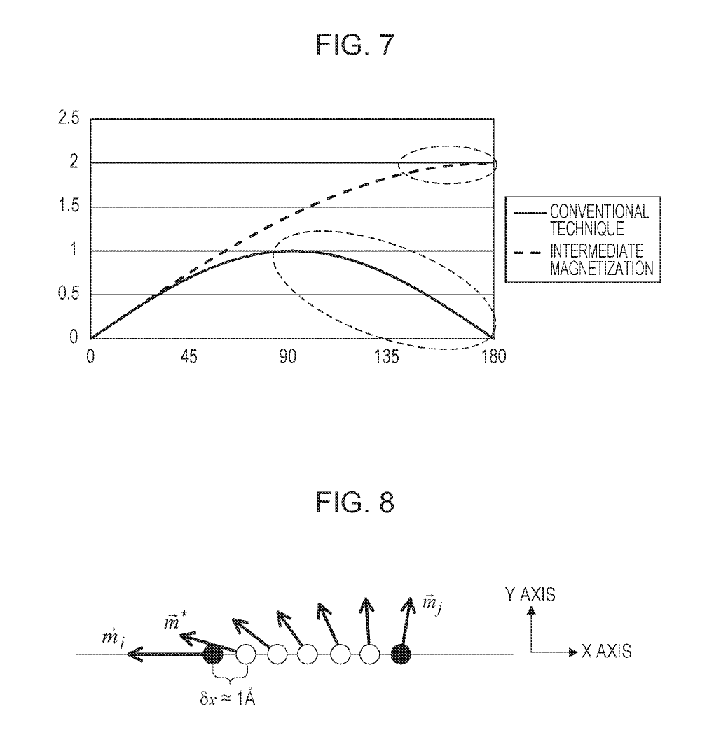

FIG. 7 is a graph that illustrates contrast to the intermediate magnetization. In the graph in FIG. 7, while the horizontal axis indicates the angle θ formed by two magnetization vectors, the Y-axis components of the gradients of the magnetization vectors are plotted, which are calculated by the “conventional technique” and the technique of the “intermediate magnetization”. The use of the intermediate magnetization enhances the calculation accuracy for the gradient of the magnetization vector, compared to the conventional technique indicated by the solid line. In the intermediate magnetization indicated by the dashed line, however, the calculation accuracy may decrease around the angle θ of 180 degrees since the gradient is saturated.

FIG. 8 is an explanatory diagram that illustrates magnetization vectors. As illustrated in FIG. 8, in the magnetic substance, atoms with magnetization vectors are included side by side while spaced by each distance of approximately iA and an angle formed by adjacent magnetization vectors is small. In the present embodiment, under the constraints related to calculator resources in calculating values, the mesh spacing is made ten times or more as large so as to be several nm or larger for example. When the value of the magnetization vector m at a position apart from a small distance ox may be acquired, the spatial gradient of the magnetization vector indicated in Mathematical Expression (30) may be calculated with higher accuracy and accordingly, the magnetic field caused through the exchange coupling may be calculated with higher accuracy. Thus, it is desired to calculate a magnetization vector positioned away from the magnetization of interest by δx in the vicinity and calculate the gradient of the magnetization vector (the magnetic field caused through the exchange coupling) using the magnetization vector.

$$\frac{d \vec{m}}{d x} = \frac{{\vec{m}}^{*} - {\vec{m}}_{i}}{δ x} \qquad ( 30 )$$

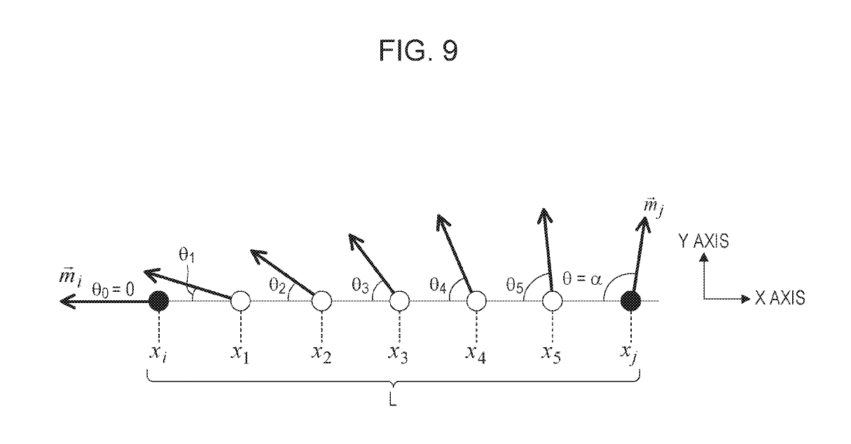

FIG. 9 is an explanatory diagram that illustrates interpolation magnetization vectors. The CPU 11 reads the magnetization vector mᵢ (a first magnetization vector) and the adjacent magnetization vector mⱼ (a second magnetization vector) from the storage part 15. As illustrated in FIG. 9, the CPU 11 generates a magnetization vector m* in the vicinity (an interpolation magnetization vector), which has an initial point on a straight line connecting the magnetization vector mᵢ and the adjacent magnetization vector mⱼ and is directed in a plane identical to the plane in which the magnetization vector mᵢ and the adjacent magnetization vector mⱼ are directed. In the example of FIG. 9, the magnetization vector m* is generated in the plane defined by the X axis and the Y axis.

The CPU 11 generates the interpolation magnetization vector based on an angle α formed by the magnetization vector mᵢ and the adjacent magnetization vector mᵢ. The angle α used hereinafter is different from a used in the above-described LLG equation. Specifically, as indicated in Mathematical Expression (31), the CPU 11 calculates the angle α of the magnetization vector m* in the vicinity by linear interpolation. Although the present embodiment describes an example using the unit magnetization vector mᵢ, the unit magnetization vector and the unit magnetization vector m* in the vicinity, the magnitude of the magnetization vector m* may be an average value of the magnetization vector mᵢ and the magnetization vector mᵢ.

$${θ}_{n} = \frac{{x}_{n}}{L} α \qquad ( 31 )$$

The gradient may be expressed by Mathematical Expression (32) when calculated using the magnetization vector as a reference and the magnetization vector m* in the vicinity with the assumption that the reference magnetization vector mᵢ and the adjacent magnetization vector mⱼ are in the XY plane.

$$\frac{d \vec{m}}{d x} = \frac{{\vec{m}}^{*} - {\vec{m}}_{i}}{Δ x} \{ \begin{matrix}\frac{d \vec{m}}{d x} {{\vert}_{x} = \frac{cos ( Δ x α ) - 1}{Δ x} \vert}_{Δ x \to 0} & X - axis component \\ \frac{d \vec{m}}{d x} {{\vert}_{y} = \frac{sin ( Δ x θ )}{Δ x} \vert}_{Δ x \to 0} & Y - axis component\end{matrix} \qquad ( 32 )$$

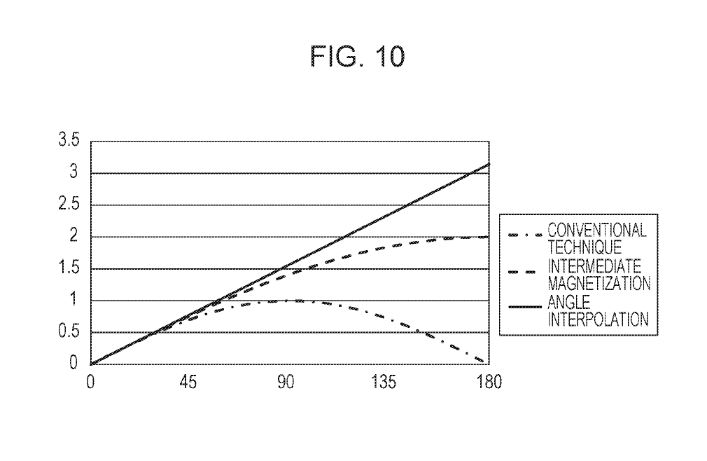

Since the force that rotates the magnetization vector mᵢ is the component in the vertical direction of the magnetization vector mᵢ, the Y-axis component that is the vertical component is plotted in a graph. FIG. 10 is the graph, which illustrates contrast to an interpolation magnetization vector. The horizontal axis indicates the angle θ formed by the two magnetization vectors and the vertical axis indicates the gradient of the magnetization vector. The Y-axis components of the gradients of the magnetization vectors calculated by the conventional technique, the technique of the intermediate magnetization, and the technique of the angle interpolation are indicated by the solid line, the dashed line, and the alternate long and short dashed lines, respectively.

As described above, the use of the angle interpolation may avoid attenuation of the gradient of the magnetization vector even when the angle formed by the magnetization vectors is large. When the rotation is postulated, the gradient is independent of the position of a differentiation Δx and remains invariant and therefore, the angle interpolation is theoretically correct. That is, the use of the angle interpolation may enable the magnetic field caused through the exchange coupling to be calculated with higher accuracy.

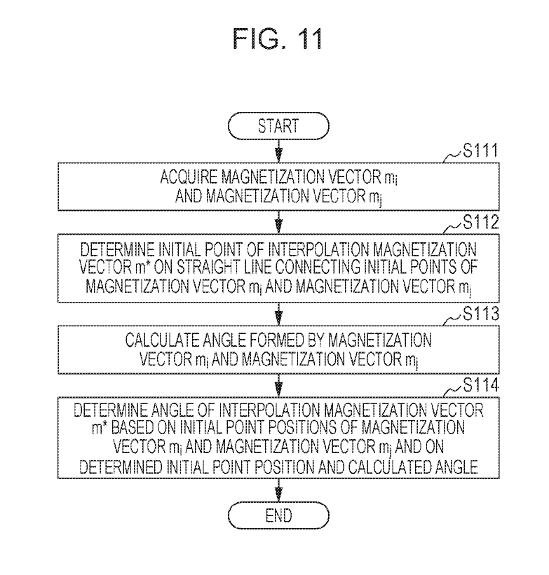

FIG. 11 is a flow chart that illustrates the procedure of the generation process of an interpolation magnetization vector. The CPU 11 reads the magnetization vector mᵢ and the magnetization vector mⱼ from the storage part 15 (step S111). In step S5111, it is assumed that the unit magnetization vector mᵢ and the unit magnetization vector mⱼ, which are directed in the XY plane, is used. The CPU 11 determines the initial point of the interpolation magnetization vector m* at a position on the straight line that connects the initial points of the magnetization vector mᵢ and magnetization vector mⱼ (step S112). The determination process of the position of the initial point is described below. The CPU 11 calculates the angle formed by the magnetization vector mᵢ and the magnetization vector mⱼ (step S113). The angle is in a clockwise direction based on the magnetization vector mᵢ.

The CPU 11 determines the angle of the interpolation magnetization vector m* in the XY plane based on the initial point positions of the magnetization vector mᵢ and the magnetization vector the initial point position determined in step S112, and the angle calculated in step S113 (step S114). Thus, the magnetic field caused through the exchange coupling may be calculated with higher accuracy.

### Embodiment 2

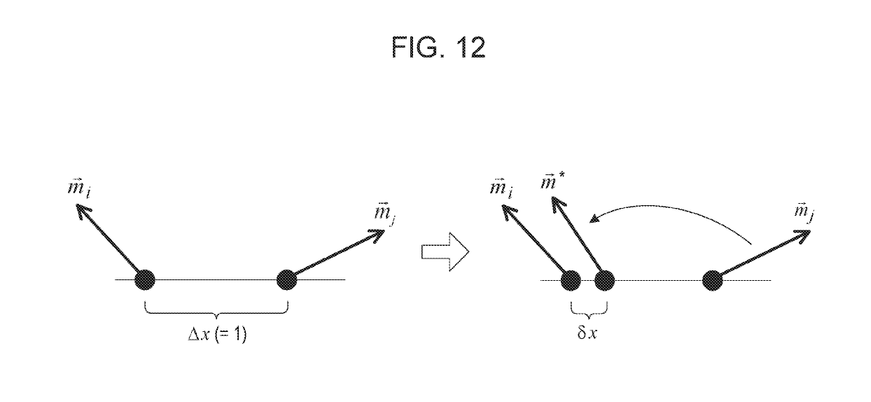

Embodiment 2 relates to a variation where a magnetization vector that has undergone the angle interpolation is applied to the linear implicit method. FIG. 12 is an explanatory diagram that illustrates magnetization vectors. In applying an interpolation magnetization vector to the linear implicit method, a magnetization vector mⱼ adjacent to a magnetization vector mᵢ of interest is rotated and made closer to the magnetization vector mᵢ. The resultant magnetization vector in the vicinity is denoted as m*. The CPU 11 reads a magnetization vector mᵢⁿ and a magnetization vector mᵢⁿ at time point n from the storage part 15. The CPU 11 reads Mathematical Expression (33) from the storage part 15 and calculates an angle α formed by the magnetization vector mᵢⁿ and the magnetization vector mᵢⁿ at the time point n. The CPU 11 reads Mathematical Expression (34) from the storage part 15 and calculates a unit vector t, which is vertical with respect to the magnetization vector mᵢⁿ and the magnetization vector mᵢⁿ at the time point n.

$$\begin{matrix}α = arccos ( {\vec{m}}_{i}^{n} \cdot {\vec{m}}_{j}^{n} ) & ( 33 ) \\ \vec{t} = \frac{{\vec{m}}_{j}^{n} \times {\vec{m}}_{i}^{n}}{\vert {\vec{m}}_{j}^{n} \times {\vec{m}}_{i}^{n} \vert} \\ \vec{t} \text{:} Unit vector of Rotation axis & ( 34 )\end{matrix}$$

The CPU 11 calculates a distance ox in accordance with the angle α. The calculation procedure is described in detail below. In the angle interpolation, the calculation accuracy of the gradient may be increased by making an adjacent magnetization vector closer to a magnetization vector of interest. When the adjacent magnetization vector is made too close (δx→0), however, nondiagonal components in simultaneous equations become large, that is, the contribution of the adjacent magnetization vector becomes large, and unstable calculation or increase in number of repeats of convergence occurs. Thus, the preferable distance δx is calculated in advance based on the angle formed by the magnetization vectors. The value of δx is desired to be as large as possible while maintaining the accuracy of the gradient calculation.

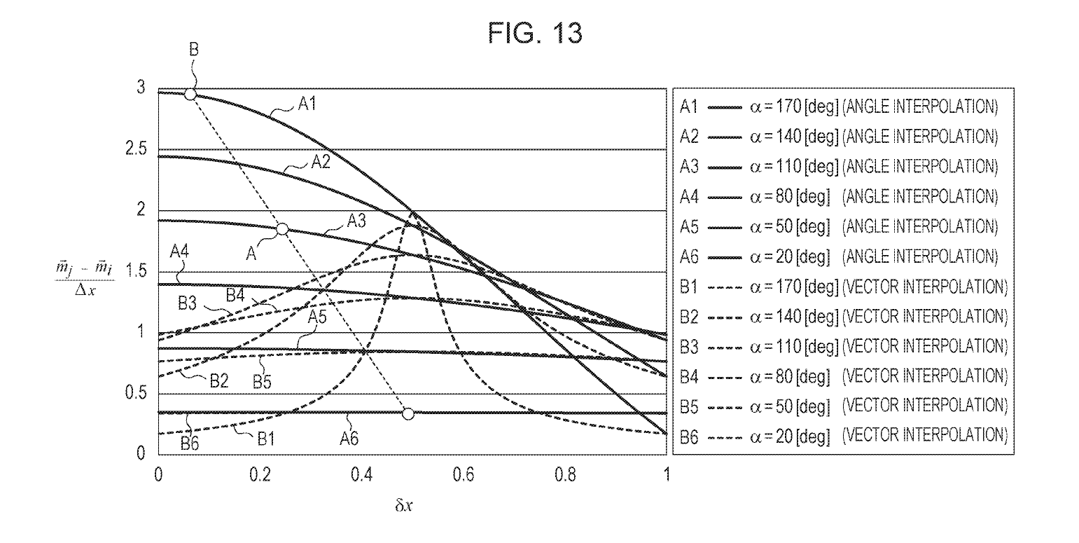

FIG. 13 is a graph that illustrates magnetization vectors. The horizontal axis indicates the position, also denoted as δx, of a virtual magnetization vector adjacent to the magnetization vector of interest and the vertical axis indicates the gradient of the magnetization vector. When the position of the adjacent magnetization vector is denoted as 1, the magnetization vector interpolated at the position δx is denoted as m*. The magnetization vector m^{*} is calculated by the “angle interpolation”, which includes A1 to A6 indicated by the solid lines, or by the “vector interpolation”, which includes B1 to B6 indicated by the dashed lines. The true value of the gradient of the magnetization vector is a value in the angle interpolation, which causes δx→0. In the vector interpolation, the value is largest and the accuracy is highest at an intermediate position, that is, when δx=0.5. Since in the angle interpolation, δx→0 is the true value of the gradient, the calculation accuracy of the gradient may be maintained even when ox is increased as the angle α decreases.

When the two magnetization vectors are close to a parallel or an anti-parallel state, it is difficult to calculate a vertical vector of the two vectors. When the two magnetization vectors are parallel, the gradient may be calculated accurately enough by a conventional calculation method. Thus, in the present embodiment, the angle interpolation is applied to the linear implicit method when the value of a is included in the range designated in advance.

Since the angle interpolation is applied to the linear implicit method when α_min<α<α_max, the CPU 11 sets values for α_min and α_max first (filtering). Parameters are described below, which include n: the number of steps of time integration, α_min: the lower limit value of the angle α formed by two magnetization vectors in a case where the angle interpolation is used, where when α<α_min, the conventional technique is used, α_max: the upper limit value of the angle α formed by the two magnetization vectors in the case where the angle interpolation is used, where when α_max<α, the conventional technique is used, and δx_min: the lower limit value of δx. When δx<δx_min in calculating δx expressed by the linear expression of a from α, δx=δx_min. Further included are δx_{A}: the value of δx at a position A in the graph, α_{A}: the value of α at the position A in the graph, δx_{B}: the value of δx at a position B in the graph, and α_{B}: the value of α at the position B in the graph.

Since convergence deteriorates when Δx is small, the CPU 11 sets the value of δx_min in advance, which is minimized. In accordance with the calculation results in the graph illustrated in FIG. 13, the CPU 11 determines a relation between δx and a so that α_{A}=80 degrees while δx_{A}=0.3 (the position A), α_{B}=170 degrees, and δx_{B}=0.0 (the position B). Also, the setting is performed so that δx_min=0.1. Based on the two pairs of combinations of the angles and distances, the CPU 11 generates a straight line that allows the angle a to pass through the two points as indicated in Mathematical Expression (35).

$$δ x = f ( α ) = - \frac{0.3}{90} α + \frac{17}{30} \qquad ( 35 )$$

Accordingly, when expression with the function of a in view of the minimum value is attempted, Mathematical Expression (36) may be obtained.

δx(α)=min(δx_min, f(α)) (36)

Subsequently, the CPU 11 generates a rotation matrix T, which is indicated in Mathematical Expression (37), using the value of ox.

$${T}_{nm} = {I}_{nm} cos ( s α ) + ( 1 - cos ( s α ) ) {t}_{n} {t}_{m} + ( \begin{matrix}0 & - {t}_{z} & {t}_{y} \\ {t}_{z} & 0 & - {t}_{x} \\ - {t}_{y} & {t}_{x} & 0\end{matrix} ) sin ( s α ) \\ where , s = 1.0 - δ x \qquad ( 37 )$$

The rotation matrix T is a matrix for rotating the magnetization vector mⱼⁿ⁺¹ adjacent to the magnetization vector mᵢⁿ⁺¹ of interest by angle α(1.0−δx) about a rotation axis That is, the rotation matrix T is a matrix by which the magnetization vector mⱼⁿ⁺¹ at the time point n+1 is multiplied so as to approach the magnetization vector mⱼⁿ⁺¹. Here, rotating the magnetization vector mⁿ⁺¹ of interest to have m^{*,n+1} is insufficient to contribute the stabilization of the calculation. By forming the magnetization vector m^{*,n+1} in the vicinity through the multiplication performed on the adjacent magnetization vector, “increase in each time increment”, which is a feature of the linear implicit method, may be achieved.

Mathematical Expression (38) is a conversion equation for making the magnetization vector mⱼⁿ⁺¹ closer to the magnetization vector m^{*,n+1} in the vicinity of the magnetization vector mᵢⁿ⁺¹ using the matrix T. The CPU 11 reads Mathematical Expression (38) and multiplies the magnetization vector mⱼⁿ⁺¹ by the matrix T to calculate the magnetization vector m*,ⁿ⁺¹ in the vicinity.

m\vec{m}^{*,n+1}=T\vec{m}ⱼⁿ⁺¹ (38)

Since the magnetization vector m* in the vicinity may be expressed with the adjacent magnetization vector mⱼⁿ⁺¹ at the time point n+1 accordingly, the linear implicit method may be applied to the angle interpolation. Thus, the exchange coupling magnetic field using the angle interpolation may be expressed by Mathematical Expression (39).

$${\vec{H}}_{ex}^{n + 1} = \frac{1}{d {V}_{i}} \frac{2 A}{{M}_{S}} {\sum }_{j = 1}^{Nf} \frac{{\vec{m}}_{ij}^{* , n + 1} - {\vec{m}}_{i}^{n + 1}}{δ x {L}_{ij}} {\vec{n}}_{j} \cdot {\vec{l}}_{j} d {S}_{j} = \frac{1}{d {V}_{i}} \frac{2 A}{{M}_{S}} {\sum }_{j = 1}^{Nf} \frac{{Tm}_{j}^{n + 1} - {\vec{m}}_{i}^{n + 1}}{δ x {L}_{ij}} {\vec{n}}_{j} \cdot {\vec{l}}_{j} d {S}_{j} \qquad ( 39 )$$

The second term on the right-hand side of Mathematical Expression (39) is a term that expresses the virtual magnetization vector m^{*,n+1} with the adjacent magnetization vector mⱼⁿ⁺¹. In course of convergence into a stable state, mⁿ equals mⁿ⁺¹ and thus, calculating the rotation axis of the rotation matrix T using the magnetization vector at the time point n brings no problem to the calculation accuracy after the convergence. In the conventional technique, the matrices of the exchange coupling of the element i and the element j are the same. The matrices of the exchange coupling of the element i and the element j using the angle interpolation are different, however. So, the coefficient matrix of the exchange coupling of the element i is denoted as G_{i,ex} and the coefficient matrix of the exchange coupling of the element j is denoted as G_{i,ex}. In the conventional technique, Gₐₙ and Fi are the same in value.

Mathematical Expression (39) enables the coefficients to be expressed by Mathematical Expressions (40) and (41).

$$\begin{matrix}{G}_{ij , ex} = \frac{γ A}{{M}_{s} d {V}_{i}} \frac{{\vec{l}}_{j} \cdot {\vec{n}}_{j}}{{L}_{ij} δ x} d {S}_{j} ( \begin{matrix}1 - {m}_{i , x}^{n} {m}_{i , x}^{n} & - {m}_{i , y}^{n} {m}_{i , x}^{n} & - {m}_{i , z}^{n} {m}_{i , x}^{n} \\ - {m}_{i , x}^{n} {m}_{i , y}^{n} & 1 - {m}_{i , y}^{n} {m}_{i , y}^{n} & - {m}_{i , z}^{n} {m}_{i , y}^{n} \\ - {m}_{i , x}^{n} {m}_{i , z}^{n} & - {m}_{i , y}^{n} {m}_{i , z}^{n} & 1 - {m}_{i , z}^{n} {m}_{i , z}^{n}\end{matrix} ) & ( 40 ) \\ {G}_{ij , ex}^{adj} = \frac{γ A}{{M}_{s} d {V}_{i}} \frac{{\vec{l}}_{j} \cdot {\vec{n}}_{j}}{{L}_{ij} δ x} d {S}_{j} ( \begin{matrix}1 - {m}_{i , x}^{n} {m}_{i , x}^{n} & - {m}_{i , y}^{n} {m}_{i , x}^{n} & - {m}_{i , z}^{n} {m}_{i , x}^{n} \\ - {m}_{i , x}^{n} {m}_{i , y}^{n} & 1 - {m}_{i , y}^{n} {m}_{i , y}^{n} & - {m}_{i , z}^{n} {m}_{i , y}^{n} \\ - {m}_{i , x}^{n} {m}_{i , z}^{n} & - {m}_{i , y}^{n} {m}_{i , z}^{n} & 1 - {m}_{i , z}^{n} {m}_{i , z}^{n}\end{matrix} ) T & ( 41 )\end{matrix}$$

Thus, simultaneous equations using the angle interpolation may be expressed by Mathematical Expression (42).

$$( \frac{I}{Δ t} + {G}_{i , an} + {G}_{ij , ex} ) ( \begin{matrix}\begin{matrix}{m}_{i , x}^{n + 1} \\ {m}_{i , y}^{n + 1}\end{matrix} \\ {m}_{i , z}^{n + 1}\end{matrix} ) - {G}_{ij , ex}^{adj} ( \begin{matrix}{m}_{j , x}^{n + 1} \\ {m}_{j , y}^{n + 1} \\ {m}_{j , z}^{n + 1}\end{matrix} ) = {\vec{F}}_{i}^{n} \qquad ( 42 )$$

A method of creating overall simultaneous equations is now described. In the description about the coefficient matrices, the relation between the element i and the element j adjacent to the element i is used. Since, in actuality, the number of elements that are present equals the number of meshes, the number of magnetization vectors allocated to the elements equals the number of meshes. Described below is a creation procedure of simultaneous equations for six elements provided with numbers one to six. Mathematical Expression (41) is an equation for the element i in view of the element j adjacent to the element i.

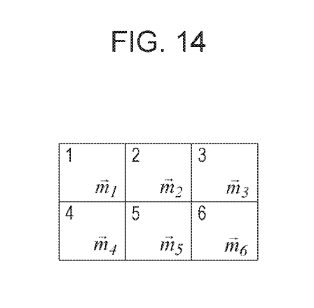

FIG. 14 is an explanatory diagram that illustrates magnetization vectors. The method of creating the simultaneous equations for the magnetization vectors of all the elements in FIG. 13 is described. Although the number of simultaneous equations of the magnetization vectors for the six elements is 6×3=18, the number of simultaneous equations is six when the simultaneous equations are expressed with the magnetization vectors. To simplify the indication below, the simultaneous equations are created by regarding each magnetization vector as an unknown quantity.

The simultaneous equations where mᵢ is expressed with the vectors may be expressed by Mathematical Expression (43).

$$( \frac{I}{Δ t} + {G}_{i , an} + {G}_{ij , ex} ) {\vec{m}}_{i}^{n + 1} - {G}_{ij , ex}^{adj} {\vec{m}}_{i}^{n + 1} = {\vec{F}}_{i}^{n} \qquad ( 43 )$$

The simultaneous equations determine a sum by taking all combinations of the element j adjacent to the element i into account. For example, the elements adjacent to the element 1 are the elements 2 and 4 and accordingly, in the coefficient matrix A in the first row, A_{1,1}, A_{1,2}, and A_{1,4} indicate non-zero and the rest indicate zero. Similarly, when simultaneous equations are created using the adjacent relations among the elements, Mathematical Expression (44) is obtained.

$$( \begin{matrix}{A}_{1 , 1} & {A}_{1 , 2} & 0 & {A}_{1 , 4} & 0 & 0 \\ {A}_{2 , 1} & {A}_{22} & {A}_{2 , 3} & 0 & {A}_{2 , 5} & 0 \\ 0 & {A}_{3 , 2} & {A}_{3 , 3} & 0 & 0 & {A}_{3 , 6} \\ {A}_{4 , 1} & 0 & 0 & {A}_{4 , 4} & {A}_{4 , 5} & 0 \\ 0 & {A}_{5 , 2} & 0 & {A}_{5 , 4} & {A}_{5 , 5} & {A}_{5 , 6} \\ 0 & 0 & {A}_{6 , 3} & 0 & {A}_{6 , 5} & {A}_{6 , 6}\end{matrix} ) ( \begin{matrix}{\vec{m}}_{1}^{n + 1} \\ {\vec{m}}_{2}^{n + 1} \\ {\vec{m}}_{3}^{n + 1} \\ {\vec{m}}_{4}^{n + 1} \\ {\vec{m}}_{5}^{n + 1} \\ {\vec{m}}_{6}^{n + 1}\end{matrix} ) = ( \begin{matrix}{\vec{F}}_{1}^{n} \\ {\vec{F}}_{2}^{n} \\ {\vec{F}}_{3}^{n} \\ {\vec{F}}_{4}^{n} \\ {\vec{F}}_{5}^{n} \\ {\vec{F}}_{6}^{n}\end{matrix} ) \qquad ( 44 )$$

Specific values of A₁,₁, A₁,₂, and A₁,₄ may each be expressed by Mathematical Expression (45).

$${A}_{1 , 1} = ( \frac{I}{Δ t} + {G}_{1 , an} + {G}_{12 , ex} + {G}_{14 , ex} ) \\ {A}_{1 , 2} = - {G}_{12 , ex}^{adj} \\ {A}_{1 , 4} = - {G}_{14 , ex}^{adj} \qquad ( 45 )$$

The coefficient matrix A may be expressed by Mathematical Expression (46) when generalized.

$${A}_{i , i} = ( \frac{I}{Δ t} + {G}_{i , an} + {\sum }_{j ∈ adj} {G}_{ij , ex} ) \\ {A}_{1 , 2} = - {G}_{12 , ex}^{adj} \\ j ∈ adj \text{:} All adjacent elements j \qquad ( 46 )$$

When the number of elements is N, simultaneous equations with the size of 3N×3N, where each magnetization vector component is an unknown quantity, are created by the above-described techniques.

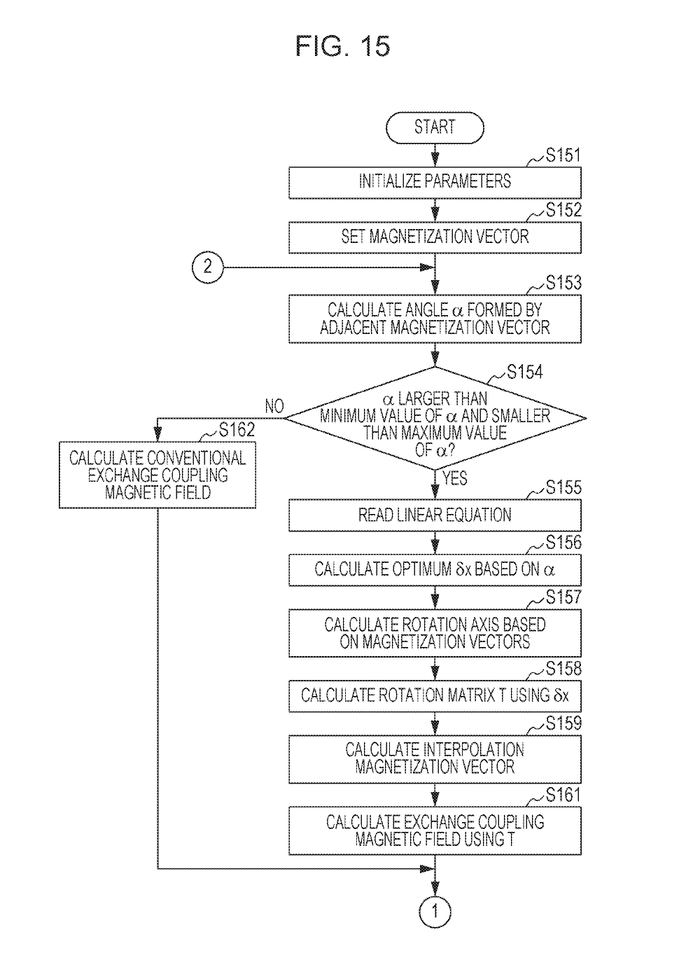

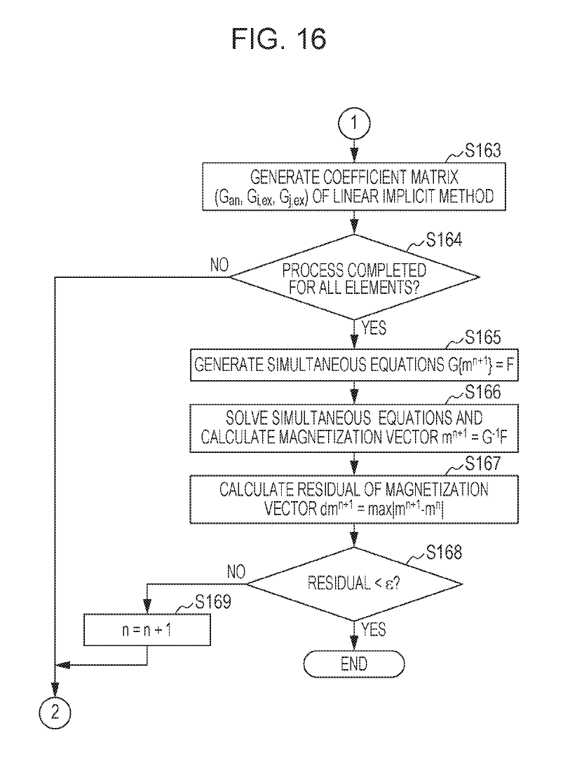

FIGS. 15 and 16 are flow charts that illustrate a calculation procedure of an exchange coupling magnetic field. The CPU 11 initializes parameters (step S151). Specifically, the CPU 11 sets n to 0 and sets ε, αmax, αmin, δx_min, α_{A}, δx_{A}, α_{B}, and δx_{B} to predetermined values. The CPU 11 sets a magnetization vector (step S152). The CPU 11 acquires an adjacent magnetization vector. The CPU 11 calculates an angle α formed by the adjacent magnetization vectors by referring to Mathematical Expression (33) (step S153).

The CPU 11 determines whether or not the calculated angle α is larger than the minimum value of a initialized in step S151 and is smaller than the maximum value of a (step S154). When the CPU 11 determines that the calculated angle α is larger than the minimum value of a initialized and is smaller than the maximum value of a (YES in step S154), the CPU 11 causes the process to proceed to step S155. The CPU 11 reads a linear equation (see Mathematical Expression (35)), which is defined based on two pairs of distances and angles initialized in step S151, that is, α_{A}, δx_{A}, α_{B}, and δx_{B}, from the storage part 15 (step S155).

The CPU 11 calculates optimum δx based on the angle α by referring to Mathematical Expressions (35) and (36) (step S156). The CPU 11 calculates the rotation axis based on the magnetization vectors that are adjacent to each other at the time point n by referring to Mathematical Expression (34) (step S157). The CPU 11 calculates the rotation matrix T using δx by referring to Mathematical Expression (37) (step S158).

The CPU 11 calculates an interpolation magnetization vector at the time point n+1, which is after the time point n, by referring to Mathematical Expression (38) (step S159). The CPU 11 calculates the exchange coupling magnetic field using the rotation matrix T by referring to Mathematical Expression (39) (step S161). After that, the CPU 11 causes the process to proceed to step S163. When the CPU 11 does not determine that the calculated angle α is larger than the minimum value of a initialized and is smaller than the maximum value of a (NO in step S154), the CPU 11 causes the process to proceed to step S162.

The CPU 11 calculates a conventional exchange coupling magnetic field by referring to Mathematical Expression (13) (step S162). After that, the CPU 11 causes the process to proceed to step S163. The CPU 11 generates a coefficient matrix (Gₐₙ, G_{i,ex}, G_{i,ex}) of the linear implicit method by referring to Mathematical Expressions (40) to (42) (step S163).

The CPU 11 determines whether or not the above-described process is complete for all the elements of the magnetization vectors (step S164). When the CPU 11 determines that the above-described process is incomplete (NO in step S164), the CPU 11 returns the process to step S153. When the CPU 11 determines that the above-described process is complete (YES in step S164), the CPU 11 causes the process to proceed to step S165. The CPU 11 generates simultaneous equations G{mⁿ⁺¹}=F by referring to Mathematical Expressions (43) to (46) (step S165).

The CPU 11 calculates a magnetization vector mⁿ⁺¹=G⁻¹F by solving the simultaneous equations (step S166). The CPU 11 calculates a residual dmⁿ⁺¹ =max|mⁿ⁺¹−mⁿ| of the magnetization vector (step S167). The CPU 11 determines whether or not the residual is smaller than c initialized in step S151 (step S168). When the CPU 11 determines that the residual is not smaller (NO in step S168), the CPU 11 causes the process to proceed to step S169. The CPU 11 increments the time point n to have the time point n+1, which is after the time point n (step S169). Subsequently, the CPU 11 returns the process to step S153. When the CPU 11 determines that the residual is smaller than c (YES in step S168), the CPU 11 ends the process.

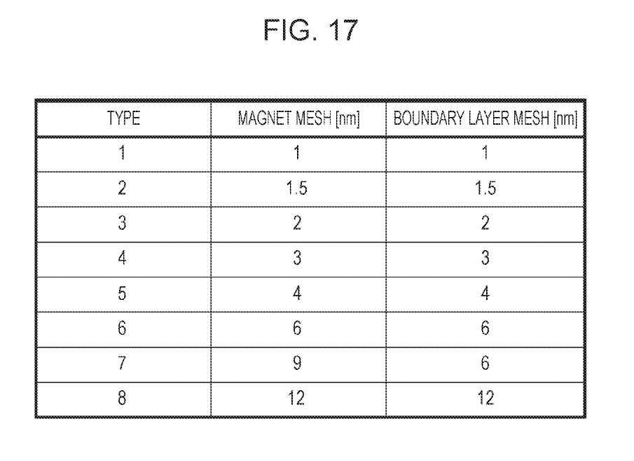

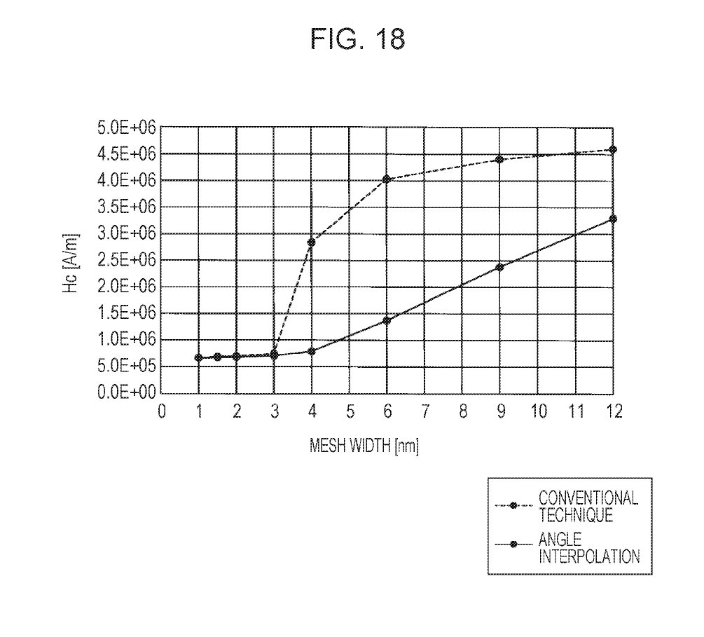

FIG. 17 is an explanatory chart that illustrates meshes used in experiments. To check advantages of the embodiment, the coercivity relative to the mesh size is calculated. Then, decrease in mesh size dependence of the coercivity is checked. Hexahedron meshes and tetrahedron meshes are used for the calculation. After that, decrease in mesh dependence of the hexahedron meshes and the tetrahedron meshes is checked. The linear implicit method is used for the calculation, and the “conventional technique” and the “angle interpolation” are applied to the calculation of the exchange coupling and compared. As illustrated in FIG. 17, eight types are prepared for each of the hexahedron meshes and the tetrahedron meshes. FIG. 17 indicates magnet meshes and boundary layer meshes. Since it is unable to create the boundary layer mesh of type 7 with size 9, size 6 is used. Hereinafter, the mesh size of each magnet is referred to as the mesh size.

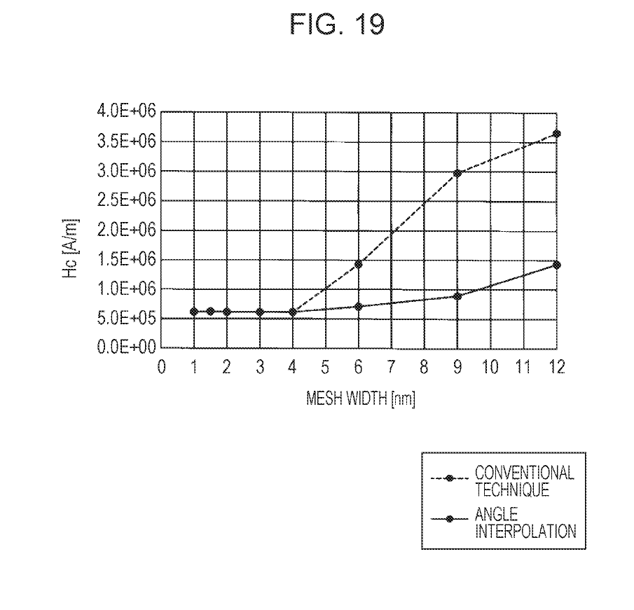

FIG. 18 is a graph that illustrates changes in coercivity of the hexahedrons and FIG. 19 is a graph that illustrates changes in coercivity of the tetrahedrons. Each horizontal axis indicates the mesh width [nm]. Each vertical axis indicates the coercivity, Hc [A/m]. As illustrated in FIGS. 18 and 19, concerning the coercivity Hc, it may be understood that the angle interpolation indicated by the solid line is less dependent on the mesh width than the conventional technique indicated by the dashed line. Thus, the calculation accuracy of the coercivity Hc may be stabilized by applying the angle interpolation to the linear implicit method. In addition, the calculation speed may be enhanced by increasing the mesh size to approximately double. As described above, the calculation speed may be enhanced so as to be ten to hundred times as high by increasing each time increment by the linear implicit method. In addition, the calculation accuracy may be increased by using an interpolation vector. Moreover, further increase in calculation speed may be achieved by applying the interpolation vector to the linear implicit method.

With regard to Embodiment 2 described above, what is not mentioned is similar to Embodiment 1 and thus, the same references are given to corresponding constituents and detailed explanations thereof are omitted.

### Embodiment 3

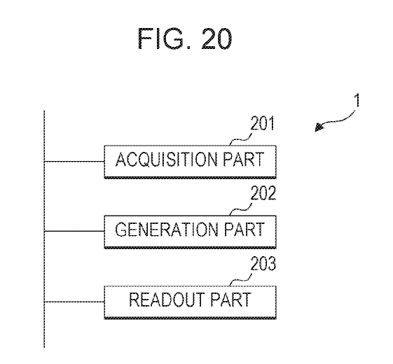

FIG. 20 is a functional block diagram that illustrates operation of the computer 1 according to the above-described embodiments. When the CPU 11 executes the control program 15P, the computer 1 operates as described below. An acquisition part 201 acquires a first magnetization vector and a second magnetization vector. A generation part 202 generates an interpolation magnetization vector that has an initial point on a straight line connecting the initial points of the acquired first magnetization vector and the acquired second magnetization vector and is directed in a plane identical to the plane in which the first magnetization vector and the second magnetization vector are directed. When an exchange coupling magnetic field of the linear implicit method is calculated, a readout part 203 reads a linear equation that indicates a relation between the distance from the initial point of the first magnetization vector to the initial point of the generated interpolation magnetization vector and the angle described above.

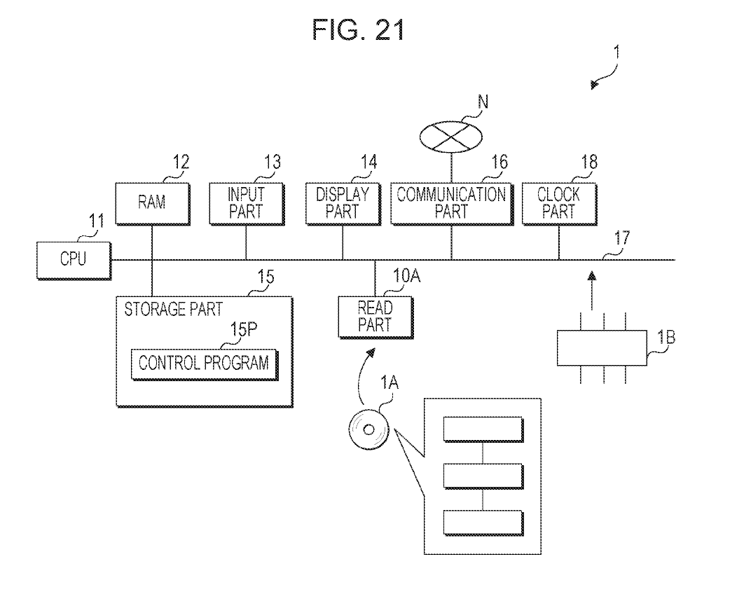

FIG. 21 is a block diagram that illustrates a hardware group of a computer 1 according to Embodiment 3. A program for operating the computer 1 may be stored in the storage part 15 by being read by a read part 10A, such as a disk drive, from a portable recording medium 1A, such as compact disc read only memory (CD-ROM), a digital versatile disc (DVD), a memory card, or universal serial bus (USB) memory. Semiconductor memory 1B, such as flash memory, which stores the program, may be included in the computer 1. Further, the program may be downloaded from another server computer (not illustrated) coupled via a communication network N, such as the Internet. The details are described below.

The computer 1 illustrated in FIG. 21 reads a program for executing various software processes described above from the portable recording medium 1A or the semiconductor memory 1B, or downloads the program from another server computer (not illustrated) via the communication network N. The program is installed as the control program 15P and loaded into the RAM 12 to be executed. Accordingly, the program functions as the above-described computer 1.

With regard to Embodiment 3 described above, what is not mentioned is similar to Embodiments 1 and 2 and thus, the same references are given to corresponding constituents and detailed explanations thereof are omitted.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An information processor for magnetic property analysis, the information processor comprising:
an acquisition part to acquire a first magnetization vector and a second magnetization vector; and
a generation part to generate an interpolation magnetization vector that has an initial point on a straight line connecting initial points of the acquired first magnetization vector and the acquired second magnetization vector and is directed in a plane identical to a plane in which the first magnetization vector and the second magnetization vector are directed.

2. The information processor for the magnetic property analysis according to claim 1, wherein
the generation part generates the interpolation magnetization vector based on an angle formed by the first magnetization vector and the second magnetization vector.

3. The information processor for the magnetic property analysis according to claim 2, the information processor further comprising:
a readout part to read a linear equation when an exchange coupling magnetic field of a linear implicit method is calculated, the linear equation indicating a relation between a distance from the initial point of the first magnetization vector to the initial point of the generated interpolation magnetization vector and the angle.

4. The information processor for the magnetic property analysis according to claim 3, wherein
the linear equation is derived based on two pairs of distances and angles.

5. The information processor for the magnetic property analysis according to claim 2, the information processor further comprising:
a calculation part to calculate a rotation matrix of the first magnetization vector with respect to the second magnetization vector when an exchange coupling magnetic field of a linear implicit method is calculated.

6. The information processor for the magnetic property analysis according to claim 5, the information processor further comprising:
a rotation axis calculation part to calculate a rotation axis of the rotation matrix based on the first magnetization vector and the second magnetization vector at first time point.

7. The information processor for the magnetic property analysis according to claim 6, wherein
the generation part generates an interpolation magnetization vector at second time point by multiplying the second magnetization vector at the second time point by the rotation matrix, the second time point being after the first time point, and
the information processor further comprises an exchange coupling magnetic field calculation part to calculate the exchange coupling magnetic field of the linear implicit method based on the generated interpolation magnetization vector.

8. A non-transitory computer-readable storage medium storing a program for magnetic property analysis, the program causing a computer to execute a process comprising:
acquiring a first magnetization vector and a second magnetization vector; and
generating an interpolation magnetization vector that has an initial point on a straight line connecting initial points of the acquired first magnetization vector and the acquired second magnetization vector and is directed in a plane identical to a plane in which the first magnetization vector and the second magnetization vector are directed.

9. An information processing method for magnetic property analysis, the information processing method causing a computer to execute a process comprising:
acquiring a first magnetization vector and a second magnetization vector; and
generating an interpolation magnetization vector that has an initial point on a straight line connecting initial points of the acquired first magnetization vector and the acquired second magnetization vector and is directed in a plane identical to a plane in which the first magnetization vector and the second magnetization vector are directed.
